(19) United States
(12) Patent Application Publication
(10) Pub. No.: US 2025/0340981 A1
(43) Pub. Date: Nov. 6, 2025

(54) FILM FORMING METHOD

(71) Applicant: Tokyo Electron Limited, Tokyo (JP)

(72) Inventor: Hiroaki ASHIZAWA, Yamanashi (JP)

(21) Appl. No.: 19/268,147

(22) Filed: Jul. 14, 2025

Related U.S. Application Data
(63) Continuation of application No. PCT/JP2024/000758, filed on Jan. 15, 2024.

(30) Foreign Application Priority Data
Jan. 25, 2023 (JP) 2023-009391

(51) Int. Cl. C23C 16/34; C23C 16/04; C23C 16/44; C23C 16/455

(52) U.S. Cl. CPC C23C 16/34; C23C 16/045; C23C 16/4407; C23C 16/4554; C23C 16/45553

(57) ABSTRACT

A film forming method includes (a) preparing a substrate in a processing chamber, (b) forming a titanium nitride film in a recess formed on the substrate by supplying a film forming gas containing a metal-containing gas to the processing chamber, (c) etching the titanium nitride film by supplying an etching gas containing a metal-containing gas to the processing chamber, and (d) repeatedly performing (b) and (c) in this order. The metal-containing gas in (b) is TiBr₄ gas or TiCl₄ gas. The metal-containing gas in (c) is TiBr₄ gas.

### CROSS-REFERENCE TO RELATED APPLICATIONS

This application is a continuation application of International Application No. PCT/JP2024/000758 filed on Jan. 15, 2024, and designated the U.S., which is based upon and claims priority to Japanese Patent Application No. 2023-009391 filed on Jan. 25, 2023, the entire contents of which are incorporated herein by reference.

### BACKGROUND

### 1. Technical Field

The present disclosure relates to a film forming method.

### 2. Description of Related Art

For example, Japanese Unexamined Patent Application Publication No. 2022-117843 (hereinafter “Patent Document 1”) proposes a substrate processing method capable of increasing filling property of a metal film when the metal film is embedded in a gap between insulating films in a substrate. In Patent Document 1, a first film forming step of supplying a film forming gas to a substrate to form a metal film in each gap, an etching step of supplying an etching gas to the substrate to etch a surface layer of the first metal film, and a second film forming step of supplying the film forming gas to the substrate to fill each gap with the metal film are performed.

Japanese Unexamined Patent Application Publication No. 2001-210713 (hereinafter “Patent Document 2”), for example, proposes that a very thin Ti (titanium) metallic film is formed on an entire substrate front surface including a bottom face in a contact hole by plasma CVD under the presence of TiCl₄ gas and H₂ gas, and then an etching step is performed. In the etching step, only TiCl₄ gas is made to flow as an etching gas, and the surface of the titanium metallic film is etched and removed by a predetermined thickness without generating plasma.

### SUMMARY

According to one aspect of the present disclosure, a film forming method includes (a) preparing a substrate in a processing chamber, (b) forming a titanium nitride film in a recess formed on the substrate by supplying a film forming gas containing a metal-containing gas to the processing chamber, (c) etching the titanium nitride film by supplying an etching gas containing a metal-containing gas to the processing chamber, and (d) repeatedly performing (b) and (c) in this order. The metal-containing gas in (b) is TiBr₄ gas or TiCl₄ gas. The metal-containing gas in (c) is TiBr₄ gas.

### BRIEF DESCRIPTION OF THE DRAWINGS

FIG. 1 is a schematic cross-sectional view illustrating an example of a substrate processing apparatus according to a first embodiment;

FIG. 2 is a diagram illustrating an example of a film forming method and a gas supply sequence in the substrate processing apparatus according to the first embodiment;

FIG. 3 is a diagram for explaining the film forming method of FIG. 2;

FIG. 4 is a diagram illustrating an example of etching results in the film forming method according to the first embodiment;

FIG. 5 is a schematic cross-sectional view illustrating an example of a substrate processing apparatus according to a second embodiment;

FIG. 6 is a diagram illustrating an example of a film forming method and a gas supply sequence in the substrate processing apparatus according to the second embodiment;

FIG. 7 is a diagram for explaining the film forming method of FIG. 6;

FIG. 8 is a diagram illustrating an example of etching results in the film forming method according to the second embodiment;

FIG. 9 is a flowchart illustrating an example of a film forming method (including a cleaning method) according to the first and second embodiments; and

FIGS. 10A and 10B are examples of a sequence of the film forming method (including the cleaning method) of FIG. 9.

### DETAILED DESCRIPTION

The present disclosure provides a film forming method capable of forming a metal-containing film having good coverage.

Hereinafter, embodiments for implementing the present disclosure will be described with reference to the drawings. In the drawings, the same components are denoted by the same reference numerals, and a duplicate description thereof may be omitted.

### First Embodiment

There is a known process of forming a titanium nitride film as a barrier metal in a recess formed on a substrate and then burying a metal to be interconnects. In this process, as the aspect ratio of a recess increases, it becomes more difficult to uniformly form a titanium nitride film in the recess. Therefore, in the first embodiment, a film forming method of forming a high-quality titanium nitride film having high throughput and good step coverage is proposed hereinafter. A substrate processing apparatus for performing this film forming method and a method of cleaning the substrate processing apparatus are also proposed hereinafter.

### <Substrate Processing Apparatus>

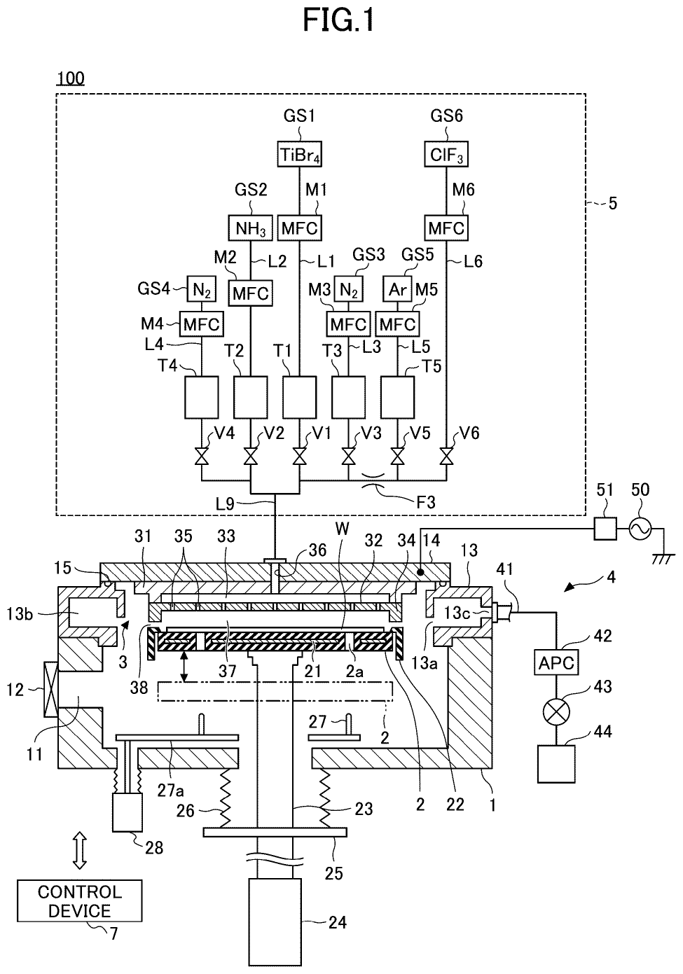

First, an example of a substrate processing apparatus 100 that performs a film forming method according to the first embodiment will be described with reference to FIG. 1. FIG. 1 is a schematic cross-sectional view illustrating an example of a substrate processing apparatus 100 according to the first embodiment.

The substrate processing apparatus 100 is an atomic layer deposition ALD) apparatus for forming a nitride titanium film (may be referred to as a “TiN film” hereinafter) on a surface of a substrate W having recesses, such as a wafer, by supplying TiBr₄ gas, which is an example of a raw material gas, and NH₃ gas, which is an example of a reducing gas, to the substrate W. The substrate processing apparatus 100 forms a TiN film on a substrate W having a recess, and then performs etching by plasma of TiBr₄ gas and argon (Ar) gas so as to widen an opening of the recess. By repeating the TiN film forming step and the etching step in this manner, a high-quality TiN film having good step coverage can be formed even in a recess having a high aspect ratio.

The substrate processing apparatus 100 includes a processing chamber 1, a stage 2, a shower head 3, an exhaust portion 4, a processing gas supply 5, and a control device 7.

The processing chamber 1 is made of a metal, such as aluminum, and has a substantially cylindrical shape. A loading/unloading port 11 for loading and unloading a substrate W is formed at a sidewall of the processing chamber 1, and the loading/unloading port 11 can be opened and closed at a gate valve 12. An annular exhaust duct 13 having a rectangular cross section is provided on the main body of the processing chamber 1. A slit 13a is formed along the inner peripheral surface of the exhaust duct 13. The exhaust duct 13 has an annular exhaust space 13b. An exhaust port 13c is formed in the outer wall of the exhaust duct 13. A ceiling 14 is provided on the upper surface of the exhaust duct 13 so as to close the upper opening of the processing chamber 1. A seal ring 15 is provided between the ceiling 14 and the exhaust duct 13, and the inside of the processing chamber 1 is thereby air-tightly sealed.

The stage 2 horizontally supports a substrate W in the processing chamber 1. The stage 2 is in the form of a disk having a size corresponding to the substrate W, and is supported by a support member 23. The stage 2 is made of a ceramic material, such as aluminum nitride (AlN) or a metal material such as aluminum or a nickel-based alloy, and a heater 21 for heating the substrate W is embedded in the stage 2. The heater 21 generates heat by being supplied with power from a heater power supply (not illustrated). A substrate W is controlled to have a predetermined temperature by controlling an output of the heater 21 in response to a temperature signal from a thermocouple (not illustrated) provided in the proximity of a substrate mounting surface, which is the upper surface of the stage 2.

A covering member 22 made of ceramics, such as alumina, is provided so as to cover an outer peripheral area of the substrate mounting surface and a side surface of the stage 2. A support member 23 extends from the center of the bottom surface of the stage 2 to the lower side of the processing chamber 1 through a hole formed in the bottom wall of the processing chamber 1, and the lower end of the support member 23 is connected to a lifting and lowering mechanism 24. The stage 2 can be lifted and lowered by the lifting and lowering mechanism 24 via the support member 23 between a processing position (indicated by a solid line in FIG. 1) and a transfer position (indicated by the two-dot chain line below the processing position) at which a substrate W can be transferred. A flange 25 is attached to the support member 23 below the processing chamber 1, and a bellows 26 that separates the atmosphere in the processing chamber 1 from the outside air and expands and contracts according to the elevating operation of the stage 2 is provided between the bottom surface of the processing chamber 1 and the flange 25.

Three support pins 27 (only two of which are illustrated) are provided in the vicinity of the bottom surface of the processing chamber 1 so as to protrude upward from a lifting and lowering plate 27a. The support pins 27 are configured to be lifted and lowered via the lifting and lowering plate 27a by a lifting and lowering mechanism 28 provided below the processing chamber 1, and can be protruded and retracted with respect to the upper surface of the stage 2 when being inserted into through-holes 2a provided in the stage 2 at the transfer position. By elevating and lowering the support pins 27 in this manner, a substrate W is transferred between a substrate transfer mechanism (not illustrated) and the stage 2.

A shower head 3 supplies a spray of a processing gas to the processing chamber 1. The shower head 3 is made of metal and mounted facing the stage 2, and has substantially the same diameter as the stage 2. The shower head 3 includes a main body 31 fixed to the ceiling 14 of the processing chamber 1 and a shower plate 32 connected to a lower portion of the main body 31. A gas diffusion space 33 is formed between the main body 31 and the shower plate 32, and a gas introduction hole 36 is provided in the gas diffusion space 33 to penetrate the main body 31 and the center of the ceiling 14 of the processing chamber 1. An annular protrusion 34 protruding downward is formed at a peripheral edge portion of the shower plate 32, and gas discharge holes 35 are formed in a flat surface inside the annular protrusion 34 of the shower plate 32.

With the stage 2 being present at the processing position, a processing space 37 is formed between the shower plate 32 and the stage 2, and the annular protrusion 34 is close to the upper surface of the stage 2 and the covering member 22 to form an annular gap 38.

The exhaust portion 4 exhausts the inside of the processing chamber 1. The exhaust portion 4 includes an exhaust line 41, a pressure adjuster (auto pressure controller, APC) 42, a valve 43, and a vacuum pump 44. One end of the exhaust line 41 is connected to the exhaust port 13c of the exhaust duct 13, and the other end is connected to a suction port of the vacuum pump 44. The pressure adjuster 42 and the valve 43 are provided between the exhaust duct 13 and the vacuum pump 44 in this order from the upstream side. The pressure adjuster 42 adjusts a pressure in the processing space 37 by adjusting a conductance of the exhaust path. The valve 43 switches between opening and closing of the exhaust line 41. During the processing, the gas in the processing space 37 reaches the exhaust space 13b of the exhaust duct 13 through the annular gap 38 and the slit 13a, and is evacuated from the exhaust port 13c of the exhaust duct 13 through the exhaust line 41 by the vacuum pump 44 of the exhaust portion 4.

The processing gas supply 5 includes a raw material gas (TiBr₄) supplying line L1, a NH₃ gas supplying line L2, a first purging line L3, and a second purging line L4. The processing gas supply 5 further includes an Ar gas supplying line L5 and a cleaning gas supplying line L6.

The raw material gas (TiBr₄) supplying line L1 extends from a raw material gas (TiBr₄) source GS1, which is a source of a metal-containing gas, for example, TiBr₄ gas, and is connected to a junction pipe L9. The junction pipe L9 is connected to the gas introduction hole 36. The raw material gas (TiBr₄) supplying line L1 is provided with a mass flow controller M1, a buffer tank T1, and an opening/closing valve V1 in this order from the raw material gas (TiBr₄) source GS1 side. The mass flow controller M1 controls a flow rate of TiBr₄ gas flowing through the raw material gas (TiBr₄) supplying line L1. The buffer tank T1 temporarily stores TiBr₄ gas and supplies a necessary amount of TiBr₄ gas in a short time. The opening/closing valve V1 switches between supplying and stopping TiBr₄ gas during an atomic layer deposition (ALD) process and an etching process.

The NH₃ gas supplying line L2 extends from an NH₃ gas source GS2 for supplying a nitrogen-containing gas, for example, and is connected to the junction pipe L9. The NH₃ gas supplying line L2 is provided with a mass flow controller M2, a buffer tank T2, and an opening/closing valve V2 in this order from the NH₃ gas source GS2 side. The mass flow controller M2 controls a flow rate of NH₃ gas flowing through the NH₃ gas supplying line L2. The buffer tank T2 temporarily stores NH₃ gas and supplies a necessary amount of NH₃ gas in a short time. The opening/closing valve V2 switches between supplying and stopping the NH₃ gas during an ALD process and an etching process.

The first purging line L3 extends from a N₂ gas source GS3, which is a source of N₂ gas, and is connected to the junction pipe L9. The first purging line L3 supplies N₂ gas during a purging step during a film formation by an ALD method. The first purging line L3 is provided with a mass flow controller M3, a buffer tank T3, and an opening/closing valve V3 in this order from the side of the N₂ gas source GS3. The mass flow controller M3 controls a flow rate of N₂ gas flowing through the first purging line L3. The buffer tank T3 temporarily stores N₂ gas and supplies a necessary amount of N₂ gas in a short time. The opening/closing valve V3 switches between supplying and stopping N₂ gas during purging in an ALD process and an etching process.

The second purging line L4 extends from an N₂ gas source GS4, which is a source of N₂ gas, and is connected to the junction pipe L9. The second purging line L4 supplies N₂ gas during a purging step during the film formation by an ALD method. The second purging line L4 is provided with a mass flow controller M4, a buffer tank T4, and an opening/closing valve V4 in this order from the N₂ gas source GS4 side. The mass flow controller M4 controls a flow rate of N₂ gas flowing through the second purging line L4. The buffer tank T4 temporarily stores N₂ gas and supplies a necessary amount of N₂ gas in a short time. The opening/closing valve V4 switches between supplying and stopping N₂ gas during purging in an ALD process and an etching process.

The Ar gas supplying line L5 extends from an Ar gas source GS5, which is a source of Ar gas, and is connected to the junction pipe L9. The Ar gas supplying line L5 is provided with a mass flow controller M5, a buffer tank T5 and an opening/closing valve V5 in this order from the Ar gas source GS5. The mass flow controller M5 controls a flow rate of Ar gas flowing through the Ar gas supplying line L5. The buffer tank T5 temporarily stores Ar gas and supplies a necessary amount of Ar gas in a short time. The opening/closing valve V5 switches between supplying and stopping Ar gas during purging in an ALD process and an etching process.

The cleaning gas supplying line L6 extends from a ClF₃ gas source GS6, which is a source of a cleaning gas (fluorine-containing gas), for example, ClF₃ gas, and is connected to the junction pipe L9. A mass flow controller M6 and an opening/closing valve V6 are provided in the cleaning gas supplying line L6 in order from the ClF₃ gas source GS6 side. The mass flow controller M6 controls a flow rate of the cleaning gas flowing through the cleaning gas supplying line L6. The opening/closing valve V6 switches between supplying and stopping ClF₃ gas during cleaning.

The ceiling 14 is connected to a radio frequency (RF) power supply 50 via a matcher 51. The RF power supply 50 supplies a radio frequency (RF) power for plasma generation.

The control device 7 controls the operation of each component of the substrate processing apparatus 100. The control device 7 includes a central processing unit (CPU), a read only memory (ROM), and a random access memory (RAM). The CPU executes a desired process according to a recipe stored in a storage area such as the RAM. In the recipe, control information of the apparatus for processing conditions is set. The control information may be, for example, a gas flow rate, a pressure, a temperature, and a process time. The recipes and the programs used by the control device 7 may be stored in, for example, a hard disk or a semiconductor memory. The recipes and the like may be stored in a portable computer-readable storage medium such as a CD-ROM or a DVD, and may be set at a predetermined position and read.

### <Film Forming Method>

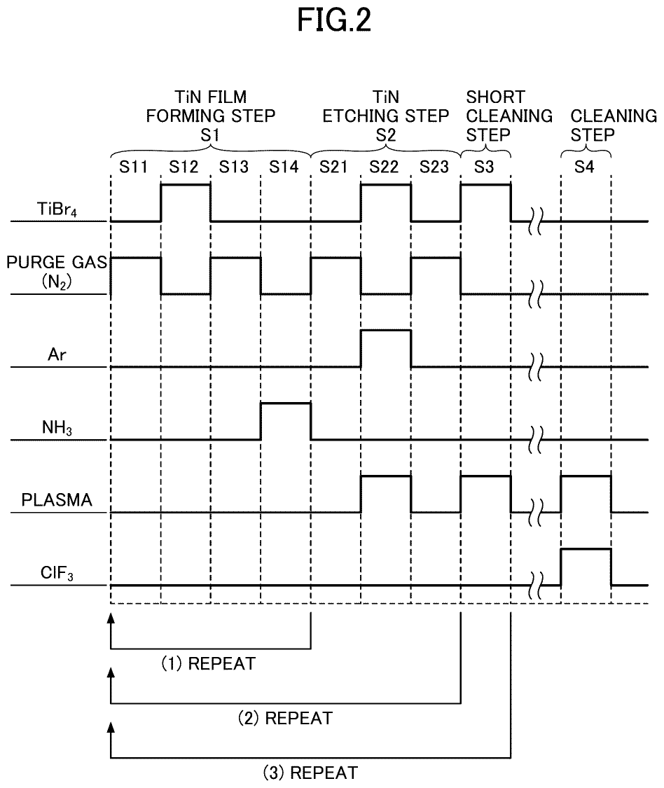

Next, a TiN film forming process as an example of a metal-containing film formed in the substrate processing apparatus 100 will be described. FIG. 2 is an example of a film forming method and a gas supply sequence performed in the substrate processing apparatus 100 according to the first embodiment.

First, a substrate W is loaded into the processing chamber 1 of the substrate processing apparatus 100 and prepared. Specifically, the gate valve 12 is opened, with the stage 2 heated to a predetermined temperature (for example, 350° C. to 530° C.) by the heater 21 being lowered to the transfer position (indicated by the two-dot chain line in FIG. 1). Subsequently, the substrate W is loaded into the processing chamber 1 through the loading/unloading port 11 by a transfer arm (not illustrated) and is supported by the support pins 27. After the transfer arm is retracted from the loading/unloading port 11, the gate valve 12 is closed. The support pins 27 are lowered to place the substrate W on the stage 2. Subsequently, the stage 2 is moved to the processing position (illustrated by the solid line in FIG. 1), and the inside of the processing chamber 1 is depressurized to a predetermined vacuum level.

### (TiN Film Forming Step S1)

Subsequently, in a TiN film forming step S1 of FIG. 2, TiBr₄ gas and NH₃ gas are alternately supplied to form a TiN film by an ALD process. The TiN film forming step S1 is a process of forming a TiN film having a desired thickness on the substrate W by repeating one or more cycles of a first purging step S11, a TiBr₄ supplying step S12, a second purging step S13, and an NH₃ supplying step S14 in this order.

In the first purging step S11, the opening/closing valves V3 and V4 are opened, and the opening/closing valves V1, V2, V5, and V6 are closed. Accordingly, N₂ gas is supplied to the processing chamber 1 from the N₂ gas source GS3 and the N₂ gas source GS4 through the first purging line L3 and the second purging line L4 to increase the pressure, thereby stabilizing the temperature of the substrate W on the stage 2. At this time, since N₂ gas is supplied to the processing chamber 1 after being temporarily stored in the buffer tanks T3 and T4, a relatively large flow rate of N₂ gas can be supplied. TiBr₄ gas is supplied from the raw material gas (TiBr₄) source GS1 to the buffer tank T1, and the pressure in the buffer tank T1 is maintained to be substantially constant.

Next, the TiBr₄ supplying step S12 is a step of supplying TiBr₄ gas as a raw material gas to the processing space 37. In the TiBr₄ supplying step S12, first, the opening/closing valve V1 is opened, while the opening/closing valves V3 and V4 are closed, thereby supplying TiBr₄ gas from the raw material gas (TiBr₄) source GS1 to the processing space 37 in the processing chamber 1 through the raw material gas (TiBr₄) supplying line L1. At this time, TiBr₄ gas is temporarily stored in the buffer tank T1 and then supplied to the processing chamber 1. Thus, TiBr₄ gas is adsorbed on the surface of the substrate W.

The TiBr₄ second purging step S13 is a step of purging excessive TiBr₄ gas and the like in the processing space 37. In the second purging step S13, the opening/closing valve V1 is closed to stop the supply of TiCl₄ gas. The opening/closing valves V3 and V4 are opened. Thus, N₂ gas is supplied from the N₂ gas source GS3 and the N₂ gas source GS4 to the processing chamber 1 through the first purging line L3 and the second purging line L4. At this time, since N₂ gas is supplied to the processing chamber 1 after being temporarily stored in the buffer tanks T3 and T4, a relatively large flow rate of N₂ gas can be supplied. Thus, excessive TiBr₄ gas and the like in the processing space 37 are purged. NH₃ gas is supplied from the NH₃ gas source GS2 to the buffer tank T2, and the pressure in the buffer tank T2 is maintained to be substantially constant.

Next, the NH₃ supplying step S14 is a step of supplying NH₃ gas to the processing space 37. In the NH₃ supplying step S14, the opening/closing valve V2 is opened, while the opening/closing valves V3 and V4 are closed. Thus, NH₃ gas is supplied from the NH₃ gas source GS2 to the processing space 37 through the NH₃ gas supplying line L2. At this time, NH₃ gas is temporarily stored in the buffer tank T2 and then supplied to the processing chamber 1. Thus, TiBr₄ adsorbed on the substrate W is reduced. The flow rate of NH₃ gas at this time can be set to an amount that causes a sufficient reducing reaction. Thus, the following chemical reaction is caused by a heat treatment using a precursor of TiBr₄ gas, and a TiN film can be formed:

$$6 {TiBr}_{4} ( g ) + 32 {NH}_{3} ( g ) = 6 TiN + 24 {NH}_{4} Br + {N}_{2} ( g )$$

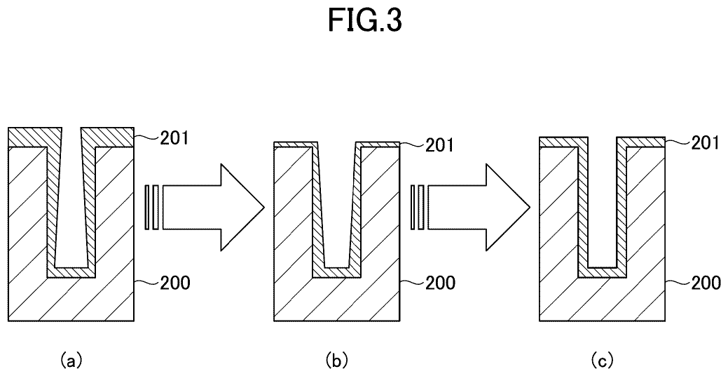

These steps S11 to S14 are repeated a predetermined number of times (“(1) Repeat” in FIG. 2). Thus, a TiN film having a desired film thickness is formed on the substrate W. Part (a) of FIG. 3 illustrates a state in which a TiN film 201 is formed in a recess formed in a base film 200 on the substrate W as a result of repeating the film forming step S1 (steps S11 through S14) a predetermined number of times. The TiN film 201 is formed to be thicker toward the upper portion. Therefore, when the number of times that “(1) Repeat” of FIG. 2 is performed increases, the opening of the recess may be blocked by the TiN film 201.

Therefore, after the ALD process of the TiN film forming step S1 of FIG. 2 is performed once or a plurality of times to form the TiN film, the surface layer of the TiN film is plasma-etched in TiN etching step S2. This widens the opening of the recess and prevents the opening of the recess from being blocked by the TiN film 201.

### (TiN Etching Step S2)

The TiN etching step S2 of FIG. 2 is a process of plasma-etching the TiN film by performing a third purging step S21, a plasma etching step S22, and a fourth purging step S23 in this order.

The third purging step S21 is a step of purging excessive NH₃ gas and the like in the processing space 37. In the third purging step S21, the opening/closing valve V2 is closed to stop the supply of NH₃ gas. The opening/closing valves V3 and V4 are opened. Thus, N₂ gas is supplied from the N₂ gas source GS3 and the N₂ gas source GS4 to the processing chamber 1 through the first purging line L3 and the second purging line L4. At this time, since N₂ gas is supplied to the processing chamber 1 after being temporarily stored in the buffer tanks T3 and T4, a relatively large flow rate of N₂ gas can be supplied. Thus, the excessive NH₃ gas and the like in the processing space 37 are purged. NH₃ gas is supplied from the NH₃ gas source GS2 to the buffer tank T2, and the pressure in the buffer tank T2 is maintained to be substantially constant.

In the next plasma etching step S22, TiBr₄ gas as etching gas and Ar gas are supplied to the processing space 37, and a radio frequency (RF) power is supplied to generate plasma for etching. In the plasma etching step S22, first, the opening/closing valves V3 and V4 are opened while the opening/closing valves V1 and V5 are closed. By opening the opening/closing valve V1, TiBr₄ gas is supplied from the raw material gas (TiBr₄) source GS1 to the processing space 37 in the processing chamber 1 through the raw material gas (TiBr₄) supplying line L1. At this time, TiBr₄ gas is temporarily stored in the buffer tank T1 and then supplied to the processing chamber 1.

By opening the opening/closing valve V5, Ar gas is supplied from the Ar raw material gas source GS5 to the processing space 37 in the processing chamber 1 through the Ar gas supplying line L5. At this time, Ar gas is temporarily stored in the buffer tank T5 and then supplied to the processing chamber 1. Ar gas contributes to stably igniting and generating plasma.

A radio frequency (RF) power for plasma generation is further supplied from the RF power supply 50. Accordingly, the following chemical reaction is caused by the plasma processing using a precursor of TiBr₄ gas, and the surface layer of the TiN film can be plasma-etched:

$$2 TiN + 4 {Br}_{4} = 2 {TiBr}_{4} ( g ) + {N}_{2} ( g )$$

The following fourth purging step S23 is a step of purging excessive TiBr₄ gas and the like in the processing space 37. In the fourth purging step S23, the opening/closing valve V1 is closed to stop the supply of TiCl₄ gas. The opening/closing valve V5 is closed to stop the supply of Ar gas. The opening/closing valves V3 and V4 are opened. Thus, N₂ gas is supplied from the N₂ gas source GS3 and the N₂ gas source GS4 to the processing chamber 1 through the first purging line L3 and the second purging line L4. At this time, since N₂ gas is supplied to the processing chamber 1 after being temporarily stored in the buffer tanks T3 and T4, a relatively large flow rate of N₂ gas can be supplied. Thus, excessive TiBr₄ gas and the like in the processing space 37 are purged. TiBr₄ gas is supplied from the raw material gas (TiBr₄) source GS1 to the buffer tank T1, and the pressure in the buffer tank T1 is maintained to be substantially constant.

Part (b) of FIG. 3 illustrates etching of the TiN film 201 in the recess on the substrate W by radicals in the plasma generated from TiBr₄ gas, as a result of performing the TiN etching step S2. The upper surface and the upper portion of the side surface of the TiN film 201 are more easily reached by the radicals and more easily etched than the bottom portion and the lower portion of the side surface, and thus the opening of the recess can be widened.

As illustrated by “(2) Repeat” in FIG. 2, after the TiN etching step S2 is performed, the process returns to the TiN film forming step S1, and the steps S11 through S14 are repeated a predetermined number of times (“(1) Repeat” in FIG. 2). Since the purging step in step S23 and the purging step in step S11 are the same step, after the TiN etching step S2 is performed, step S11 may be omitted and the TiBr₄ supplying step may be performed in the next TiN film forming step S1.

By performing the repeats (1) and (2) of FIG. 2, the TiN film 201 having good coverage as illustrated in part (c) of FIG. 3 can be formed.

In the film forming process of the substrate W described above, the TiN film is deposited on the parts including the inner wall of the processing chamber 1. Since the deposited film is peeled off to become particles and affect the film formation on the substrate W, a short cleaning step S3 illustrated in FIG. 2 is performed under predetermined conditions.

For example, when the number of times of repeatedly performing the TiN film forming step S1 and the TiN etching step S2 in the repeat (2) of FIG. 2 reaches a first set number of times that is set in advance, the substrate W is unloaded, and then the short cleaning step S3 in the processing chamber 1 is performed with TiBr₄ gas. The short cleaning step S3 is a step of etching the surface layer of the deposited TiN film and removing the deposits that cause particles.

In the short cleaning step S3, TiBr₄ gas as a cleaning (etching) gas is supplied to the processing space 37, and a radio frequency (RF) power is supplied to generate plasma, thereby performing cleaning (etching). In the short cleaning step S3, first, the opening/closing valve V1 is opened while the opening/closing valves V3 and V4 are closed. By opening the opening/closing valve V1, TiBr₄ gas is supplied from the raw material gas (TiBr₄) source GS1 to the processing space 37 in the processing chamber 1 through the raw material gas (TiBr₄) supplying line L1. At this time, TiBr₄ gas is temporarily stored in the buffer tank T1 and then supplied to the processing chamber 1.

A radio frequency (RF) power for plasma generation is supplied from the RF power supply 50. As a result, the surface layer of the TiN film deposited by the plasma of TiBr₄ gas is peeled off and removed by etching.

As illustrated by “(3) Repeat” in FIG. 2, after the short cleaning step S3 is performed, the process returns to the TiN film forming step S1, and steps S11 through S14 are repeated a predetermined number of times (“(1) Repeat” in FIG. 2), and the operation of performing the TiN etching step S2 is repeated (“(2) Repeat” in FIG. 2).

In this manner, the operation of performing the short cleaning step S3 is repeated (“(3) Repeat” in FIG. 2) during the repetition of the TiN film forming step S1 and the TiN etching step S2 (“(2) Repeat” in FIG. 2).

Thereafter, for example, when the number of times of repeatedly performing the TiN film forming step S1 and the TiN etching step S2 (the number of repeats in (2) of FIG. 2) reaches a second set number of times that is set in advance, which is larger than the first set number of times, the cleaning step S4 is performed.

In the cleaning step S4, a ClF₃ gas as a cleaning gas is supplied to the processing space 37, and a radio frequency (RF) power is supplied to generate plasma, thereby performing cleaning. In the cleaning step S4, first, the opening/closing valves V3 and V4 are opened to supply the N₂ gas to the processing chamber 1, thereby purging the excessive TiBr₄ gas and the like in the processing space 37.

Next, the opening/closing valves V3 and V4 are closed, and the opening/closing valve V6 is opened, whereby ClF₃ gas is supplied from the ClF₃ gas source GS6 to the processing space 37 in the processing chamber 1 through the cleaning gas supplying line L6. A radio frequency (RF) power for plasma generation is supplied from the RF power supply 50. Accordingly, the inside of the processing chamber 1 is cleaned by generating plasma from ClF₃ gas. After the cleaning step S4 is performed, coating with a pre-coating film is performed, and then a TiN film is formed.

### Experiment Results

### (Film Forming Step)

In the TiN film forming step S1, the stage 2 was set to 350° C. to 530° C., and TiBr₄ gas and NH₃ gas were alternately supplied to form a TiN film by heat treatment. According to this, in the above temperature range, a TiN film having good crystallinity and step coverage and a uniform film thickness was formed. In addition, as the temperature of the stage 2 increased in the above temperature range, the film formation rate increased, and the film thickness of the TiN film increased.

### (Etching Step)

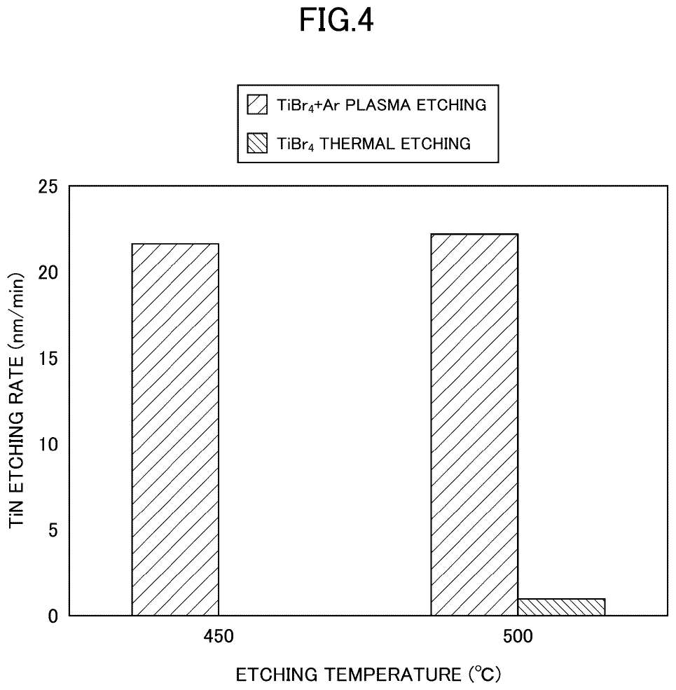

In the TiN etching step S2, the stage 2 was controlled to be the same temperature as in the TiN film forming step S1, and plasma was generated using TiBr₄ gas and Ar gas to etch the TiN film. FIG. 4 is a diagram illustrating an example of the etching results in the film forming method according to the first embodiment. In FIG. 4, the horizontal axis represents an etching temperature (temperature of the stage 2), and the vertical axis represents an etching rate of the TiN film.

When the etching temperature was 450° C., the etching rate was 22 nanometers per minute (nm/min) in the case where the TiN film was etched by generating plasma using TiBr₄ gas and Ar gas. When the etching temperature was 550° C., the etching rate was 23 nm/min in the case where the TiN film was etched by generating plasma using TiBr₄ gas and Ar gas.

In contrast, when the TiN film was etched by the heat treatment using TiBr₄ gas, the TiN film could not be etched at the etching temperature of 450° C. When the etching temperature was 500° C., the etching rate was 1 to 2 nm/min, and the TiN film was not appreciably etched.

### (Evaluation of TiN Film)

The step coverage of the TiN film was evaluated using a ratio of a film thickness of an upper film (a film on an upper surface of a recess) of the TiN film to a film thickness of a lower film (a film on a bottom surface of a recess) of the formed TiN film. When the etching temperature was 450° C. and the etching time was 30 seconds, the step coverage was 100%, and the thickness of the upper film relative to the lower film was the same.

When the etching temperature was 450° C. and the etching time was 120 seconds, the step coverage was 113%. When the etching temperature was 500° C. and the etching time was 120 seconds, the step coverage was 113%. In either case, a TiN film having good coverage was formed.

Even in the case where the TiN film was formed by the method illustrated in the film forming step S1 using TiCl₄ gas instead of TiBr₄ gas, the TiN film could be plasma-etched using TiBr₄ gas by the method illustrated in the etching step S2. The step coverage in this case was 90%.

Thus, it was found that in the case where the TiN film is etched using TiBr₄ gas, the TiN film is not appreciably etched by the heat treatment, and it is effective to generate plasma. It was also found that the TiN film formed by using TiCl₄ gas instead of TiBr4 gas can be etched by using TiBr₄ gas.

The film forming method according to the first embodiment described above includes (a) a step of preparing a substrate W in the processing chamber 1, (b) a film forming step of forming a TiN film by supplying TiBr₄ gas or a gas containing TiCl₄ gas to the processing chamber 1, (c) an etching step of etching the TiN film by supplying a gas containing TiBr₄ gas to the processing chamber 1, and (d) the film forming step (b) and the etching step (c) are repeatedly performed in this order. In the etching step (c), RF power is supplied to the processing chamber 1, and the TiN film is plasma-etched by plasma generated from TiBr₄ gas.

In the film forming step, metal-containing gases, (i.e., TiBr₄ gas and NH₃ gas, or TiCl₄ gas and NH₃ gas) are alternately supplied to form a TiN film by an ALD method. After the film forming step is performed once or a plurality of times, the etching step is performed once or a plurality of times.

The metal-containing gas supplied in the film forming step and the metal-containing gas supplied in the etching step may be the same gas (i.e., TiBr₄ gas), or may be different gases (i.e., TiCl₄ gas in the film forming step and TiBr₄ gas in the etching step).

It is preferable that the temperature of the stage 2 on which a substrate is placed be the same in the film forming step and the etching step. Furthermore, it is preferable that the temperature of the stage 2 be the same in the film forming step, the etching step, and the short cleaning step.

According to this, it is possible to provide a film forming method capable of forming a TiN film having good coverage. Since the film forming step and the etching step can be continuously performed in the same processing chamber 1, only one substrate processing apparatus 100 need be disposed, and thus, high throughput and cost merit can be obtained.

Substantially the same temperature at which the film forming step, the etching step, and the short cleaning step are performed can be set in the range of 350° C. to 530° C., and thus, the throughput can be improved.

### Second Embodiment

Next, a film forming method of forming a titanium film (hereinafter, also referred to as a “Ti film”) in a recess formed on a substrate according to a second embodiment of the present invention will be described. A substrate processing apparatus 100a for performing the film forming method and a method of cleaning the substrate processing apparatus 100a are also proposed hereinafter.

### <Substrate Processing Apparatus>

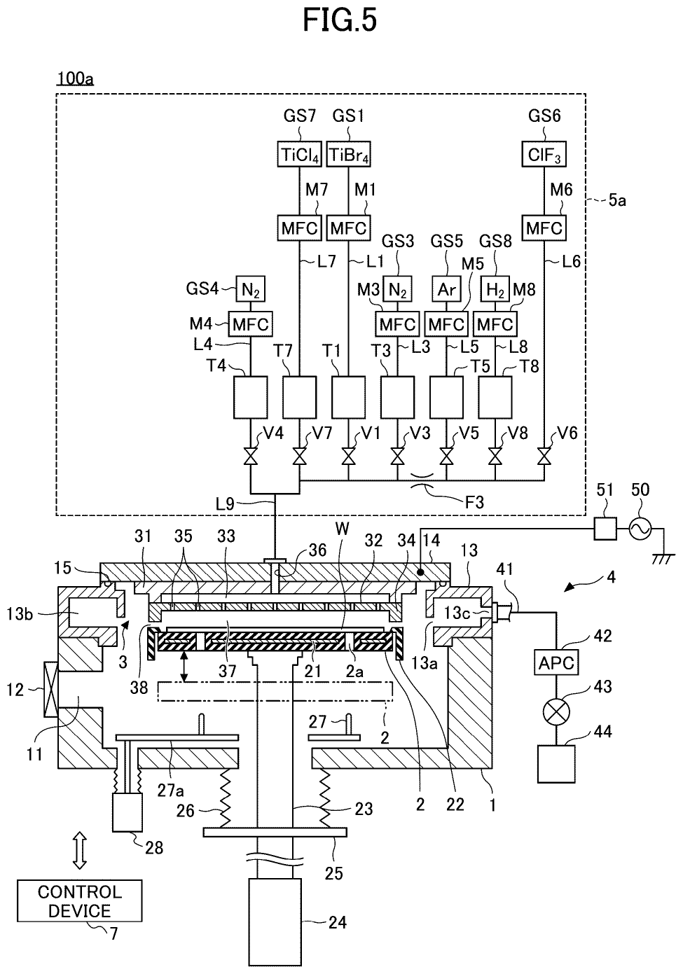

First, an example of a substrate processing apparatus 100a that performs a film forming method according to the second embodiment will be described with reference to FIG. 5. FIG. 5 is a schematic cross-sectional view illustrating an example of a substrate processing apparatus 100a according to the second embodiment.

The substrate processing apparatus 100a differs from the substrate processing apparatus 100 of FIG. 1 in the configuration of the processing gas supply 5a, and the other configurations are the same. Therefore, the processing gas supply 5a of the substrate processing apparatus 100a will be described, and the description of the other configurations will be omitted.

The processing gas supply 5a includes the raw material gas (TiBr₄) supplying line L1, the first purging line L3, and the second purging line L4. The processing gas supply 5a further includes the Ar gas supplying line L5, the cleaning gas supplying line L6, a raw material gas (TiCl₄) supplying line L7, and an H₂ gas supplying line L8.

The raw material gas (TiBr₄) supplying line L1, the first purging line L3, the second purging line L4, the Ar gas supplying line L5, and the cleaning gas supplying line L6 have the same configuration as the gas supplying lines of the processing gas supply 5, and thus the description of these lines will be omitted.

The raw material gas (TiCl₄) supplying line L7 extends from a raw material gas (TiCl₄) source GS7 which is a source of a metal-containing gas, for example, TiCl₄ gas, and is connected to the junction pipe L9. The raw material gas (TiCl₄) supplying line L7 is provided with a mass flow controller M7, a buffer tank T7, and an opening/closing valve V7 in this order from the raw material gas (TiCl₄) source GS7 side. The mass flow controller M7 controls a flow rate of TiCl₄ gas flowing through the material gas (TiCl₄) supplying line L7. The buffer tank T7 temporarily stores TiCl4 gas and supplies a necessary amount of TiCl₄ gas in a short time. The opening/closing valve V7 switches between supplying and stopping TiCl₄ gas during an ALD process and an etching process.

The H₂ gas supplying line L8 extends from an H₂ gas source GS8, for example, and is connected to the junction pipe L9. The H₂ gas supplying line L8 is provided with a mass flow controller M8, a buffer tank T8, and an opening/closing valve V8 in this order from the H₂ gas source GS8 side. The mass flow controller M8 controls a flow rate of H₂ gas flowing through the H₂ gas supplying line L8. The buffer tank T8 temporarily stores H₂ gas and supplies a necessary amount of H₂ gas in a short time. The opening/closing valve V8 switches between supplying and stopping H₂ gas during an ALD process and an etching process.

### <Film Forming Method>

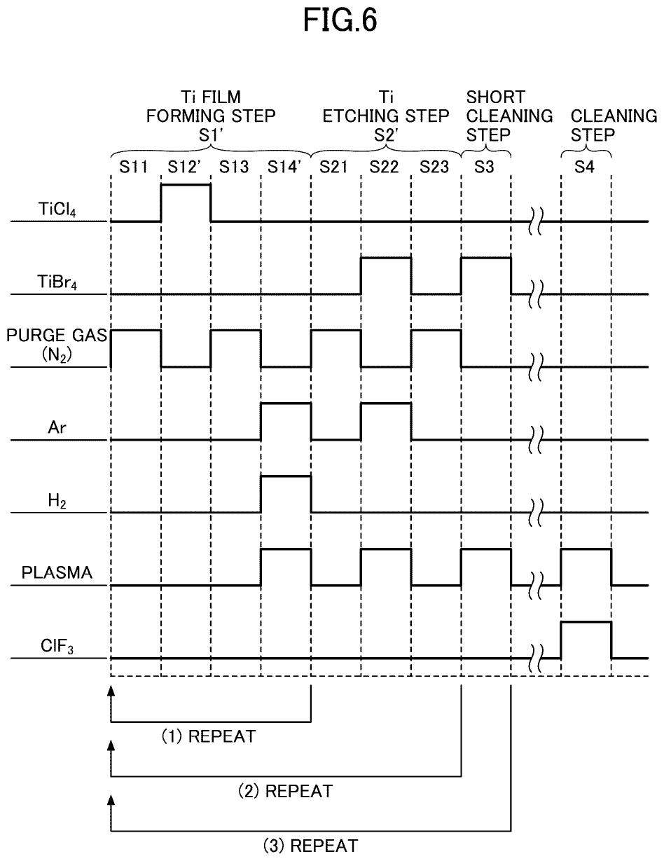

Next, a Ti film forming process as an example of a metal-containing film formed in the substrate processing apparatus 100a will be described. FIG. 6 is a diagram illustrating an example of a film forming method and a gas supply sequence in the substrate processing apparatus 100a according to the second embodiment.

First, a substrate W is loaded into the processing chamber 1 of the substrate processing apparatus 100a and prepared.

### (Ti Film Forming Step S1′)

Subsequently, in Ti film forming step S1′ of FIG. 6, a Ti film is formed by an ALD process using TiCl₄ gas and H₂ gas. The Ti film forming step S1′ is a process of forming a Ti film having a desired thickness on the substrate W by repeating one or more cycles of a first purging step S11, a TiCl₄ supplying step S12′, a second purging step S13, and an H₂ supplying step S14′ in this order.

The first purging step S11 and the second purging step S13 are the same steps as the first purging step S11 and the second purging step S13 of the first embodiment, and thus the description of these steps will be omitted.

The TiCl₄ supplying step S12′ following the first purging step S11 is a step of supplying TiCl₄ gas as a film forming gas to the processing space 37. In the TiCl₄ supplying step S12′, first, the opening/closing valve V7 is opened while the opening/closing valves V3 and V4 are closed, thereby supplying TiCl₄ gas from the material gas (TiCl₄) source GS7 to the processing space 37 in the processing chamber 1 through the raw material gas (TiCl₄) supplying line L7. At this time, TiCl₄ gas is temporarily stored in the buffer tank T7 and then supplied to the processing chamber 1. Thus, TiCl₄ gas is adsorbed on the surface of the substrate W.

The H₂ supplying step S14′ following the second purging step S13 is a step of supplying H₂ gas as to the processing space 37. In the H₂ supplying step S14′, the opening/closing valves V3 and V4 are opened while the opening/closing valves V5 and V8 are closed.

By opening the opening/closing valve V5. Ar gas is supplied from the Ar raw material gas source GS5 to the processing space 37 in the processing chamber 1 through the Ar gas supplying line L5. At this time, Ar gas is temporarily stored in the buffer tank T5 and then supplied to the processing chamber 1. Ar gas contributes to stably igniting and generating plasma.

By opening the opening/closing valve V8, H₂ gas is supplied from the H₂ gas source GS8 to the processing space 37 through the H₂ gas supplying line L8. At this time, H₂ gas is temporarily stored in the buffer tank T8 and then supplied to the processing chamber 1.

A radio frequency (RF) power for plasma generation is further supplied from the RF power supply 50. Thus, plasma is generated using H₂ gas and Ar gas.

Thus, TiCl₄ adsorbed on the substrate W reacts with H₂ gas. The flow rate of H₂ gas at this time can be set to an amount that causes a sufficient reaction. Accordingly, the following chemical reaction is caused by performing the plasma processing using the plasma of H₂ gas, and thus the Ti film can be formed. However, in this step, the following chemical reaction may be caused by heat treatment without using plasma.

$${TiCl}_{4} ( g ) + 2 {H}_{2} ( g ) = Ti + 4 HCl ( g )$$

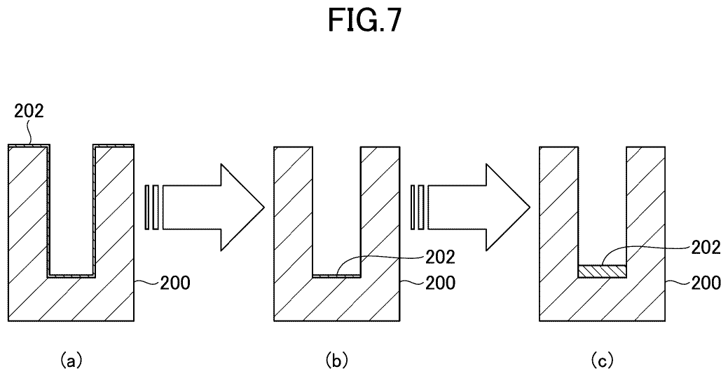

These steps S11, S12′, S13, and S14′ are repeated a predetermined number of times (“(1) Repeat” in FIG. 6). Thus, a Ti film having a desired film thickness is formed on the substrate W. Part (a) of FIG. 7 illustrates a state in which a Ti film 202 is formed in a recess formed in a base film 200 on a substrate W as a result of repeating the steps of the Ti film forming step S1′. The Ti film 202 has good crystallinity and step coverage. The Ti film 202 is formed conformally.

After the ALD process of the Ti film forming step S1′ of FIG. 6 is performed once or a plurality of times to form a Ti film, plasma etching of the Ti film is performed in the Ti etching step S2′. The Ti etching step S2′ performs the same process as steps S21 through S23 of the TiN etching step S2 according to the first embodiment. This allows the Ti film on the upper side and the side surface of the recess to be etched, and allows the Ti film to remain on the bottom surface of the upper side where TiBr₄ radicals are less likely to reach. Part (b) of FIG. 7 illustrates a state in which the Ti film 202 is removed from the upper surface and the side surface of the recess and the Ti film 202 remains on the bottom surface as a result of repeating the steps of the Ti etching step S2′.

As illustrated by “(2) Repeat” in FIG. 6, after the Ti etching step S2′ is performed, the process returns to the Ti film forming step S1′, and the steps of the Ti film forming step S1′ is repeated a predetermined number of times (“(1) Repeat” in FIG. 2). Since the purging step in step S23 and the purging step in step S11 are the same step, after the Ti etching step S2′ is performed, step S11 may be omitted and the TiCl₄ supplying step S12′ may be performed in the next Ti film forming step S1′.

By performing the repeats (1) and (2) of FIG. 6, the Ti film 202 can be formed from the bottom of the recess as illustrated in part (c) of FIG. 7. Since the short cleaning step S3 and the cleaning step S4 are the same steps as the short cleaning step S3 and the cleaning step S4 of the first embodiment, the description of these steps will be omitted.

### Experiment Results

### (Film Forming Step)

In the Ti film forming step S1′, the stage 2 was set in the range of 350° C. to 530° C., and after TiCl₄ gas was supplied, a Ti film was formed by a plasma treatment using H₂ gas and Ar gas. According to this, a uniform film was formed in the above temperature range. In addition, as the temperature of the stage 2 increased within the above temperature range, the film formation rate increased, and the film thickness of the TiN film increased.

### (Etching Step)

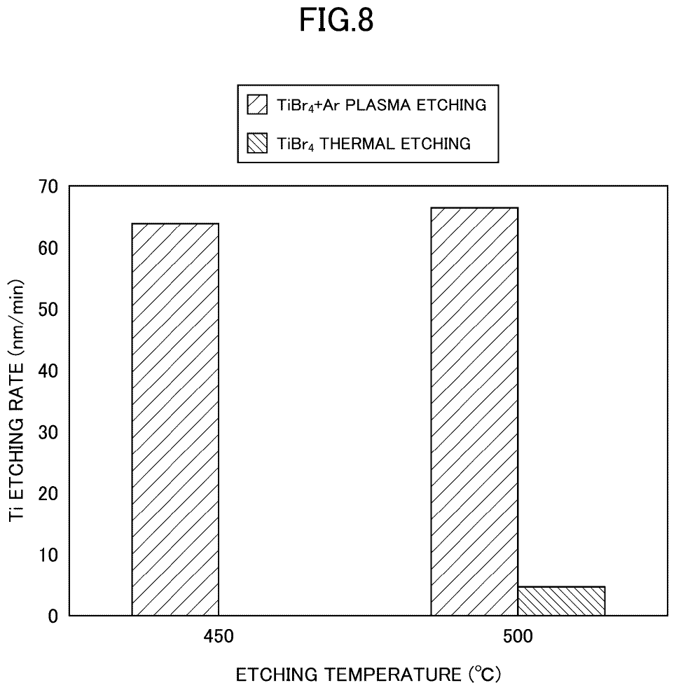

In the Ti etching step S2′, the stage 2 was set in the same temperature range as that in the Ti film forming step S1′, and plasma was generated using TiBr₄ gas and Ar gas to etch the Ti film. FIG. 8 is a diagram illustrating an example of the etching results in the film forming method according to the second embodiment. In FIG. 8, the horizontal axis represents an etching temperature (temperature of the stage 2), and the vertical axis represents an etching rate of the Ti film.

When the etching temperature was 450° C., the etching rate was 64 nanometers per minute (nm/min) in the case where the Ti film was etched by generating plasma using TiBr₄ gas and Ar gas. When the etching temperature was 500° C., the etching rate was 67 nanometers per minute (nm/min) in the case where the Ti film was etched by generating plasma using TiBr₄ gas and Ar gas.

In contrast, when the Ti film was etched by the heat treatment using TiBr₄ gas, the Ti film could not be etched at the etching temperature of 450° C. When the etching temperature was 500° C., the etching rate was 4 to 5 nm/min, and the Ti film was not appreciably etched.

Thus, it was found that in the case where the Ti film is etched using TiBr₄ gas, the TiN film is not appreciably etched by the heat treatment, and it is effective to generate plasma.

The film forming method according to the second embodiment described above includes (a) a step of preparing a substrate W in the processing chamber 1, (b) a step of forming a Ti film by supplying a gas containing the TiCl₄ gas to the processing chamber 1, (c) a step of etching the Ti film by supplying a gas containing the TiBr₄ gas to the processing chamber 1, and (d) the film forming step (b) and the etching step (c) are repeatedly performed in this order. In the etching step (c), RF power is supplied to the processing chamber 1, and the Ti film is plasma-etched by plasma generated from TiBr₄ gas.

In the film forming step (b), metal-containing gases (i.e., TiCl₄, and H₂ gas and Ar gas) are alternately supplied to form a Ti film by an ALD method.

The metal-containing gas supplied in the film forming step (b) and the metal-containing gas supplied in the etching step (c) are different gases, namely TiCl₄ gas and TiBr₄ gas, respectively.

It is preferable that the temperature of the stage 2 on which a substrate is placed be the same in the film forming step and the etching step. Furthermore, it is preferable that the temperature of the stage 2 on which a substrate W is placed be the same in the film forming step, the etching step, and the short cleaning step.

According to this, it is possible to provide a film forming method capable of improving the filling property of a Ti film to be filled into the recess. Since the film forming step and the etching step can be continuously performed in the same processing chamber 1, only one substrate processing apparatus 100 need be disposed, and thus, high throughput and cost merit can be obtained.

The same temperature at which the film forming step, the etching step, and the short cleaning step S3 are performed can be set in the range of 350° C. to 530° C., and thus, the throughput can be improved.

### <Cleaning>

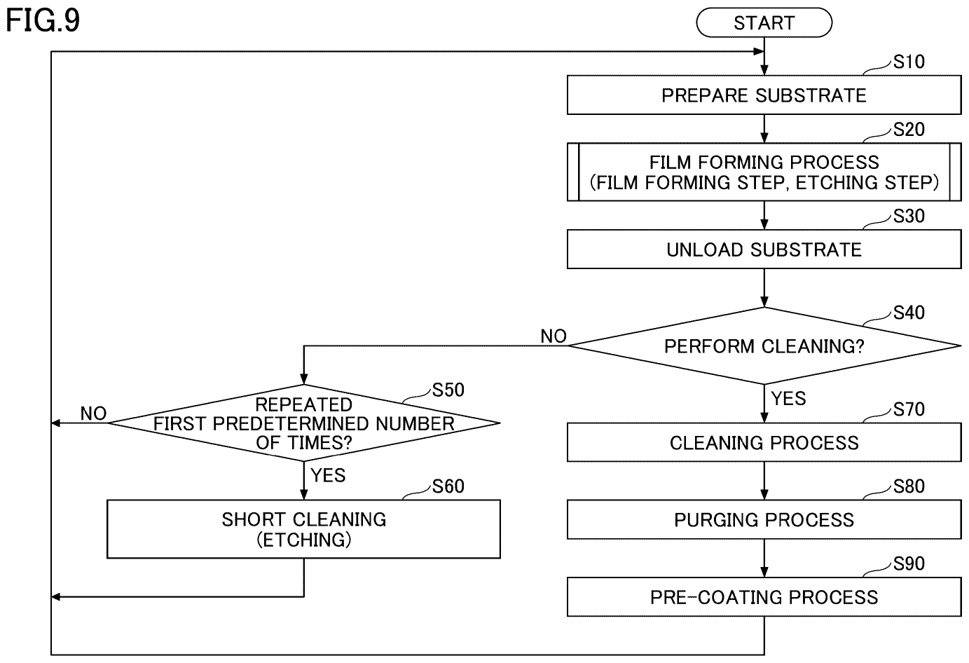

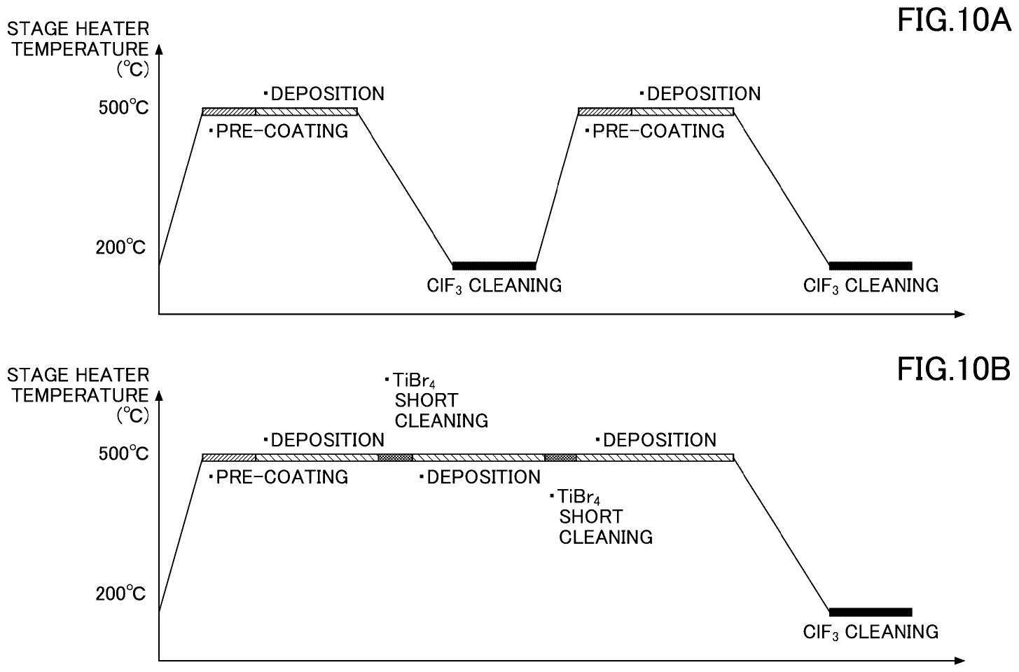

A cleaning method performed following the film forming process will be described with reference to FIG. 9 and FIGS. 10A and 10B. FIG. 9 is a flowchart illustrating an example of a film forming method (including a cleaning method) according to the first and second embodiments. FIGS. 10A and 10B are examples of a sequence of the film forming method (including the cleaning method) of FIG. 9. The process illustrated in FIG. 9 is controlled by the control device 7 and is performed by the substrate processing apparatus 100 or the substrate processing apparatus 100a.

In the film forming method illustrated in FIG. 9, a substrate is prepared in step S10, a TiN film or a Ti film is formed in step S20, and the substrate W after the film formation is unloaded in step S30. In the case where a TiN film is formed, step S20 repeatedly performs, for example, the TiN film forming step S1 and the TiN etching step S2 illustrated in FIG. 2 a predetermined number of times. In the case of forming a Ti film, in step S20, the Ti film forming step S1′ and the Ti etching step S2′ illustrated in FIG. 6, for example, are repeatedly performed a predetermined number of times. In FIG. 10B, the film forming process in step S20 is indicated by “Deposition”.

In step S40, the control device 7 determines whether or not to perform cleaning. When the control device 7 determines not to perform cleaning, the process proceeds to step S50 and the control device 7 determines whether or not “(2) Repeat” in FIG. 2 or FIG. 6 has been repeated a first set number of times.

When the control device 7 determines in step S50 that the first set number of repeats has not been reached, the control device 7 returns to step S10 and starts processing a next substrate W. On the other hand, when the control device 7 determines that the first set number of times has been performed in step S50, the control device 7 proceeds to step S60 and performs a short cleaning (etching) process using TiBr₄ gas. In FIG. 10B, the short cleaning process of step S60 is indicated by “TiBr₄ Short Cleaning”. After the short cleaning process is performed, the process returns to step S10, and the film forming process of a next substrate W is started. The short cleaning process can be performed at the same temperature (e.g., 500° C.) as the film forming temperature.

When the control device 7 determines to perform the cleaning in step S40, the control device 7 proceeds to step S70 and performs the cleaning process using ClF₃ gas. In FIG. 10B, the cleaning process of step S70 is indicated by “ClF₃ Cleaning”.

In this cleaning process, ClF₃ gas is used. Therefore, it is difficult to increase the cleaning temperature to 350° C. or higher in order to avoid corrosion of the shower head 3 and the like. Therefore, the cleaning process cannot be performed at the same temperature as the film forming temperature, and is performed at a temperature lower than 350° C. (for example, 200° C.).

In contrast, since the short cleaning process using TiBr₄ gas can be performed at the same temperature as the film formation temperature, a temperature control time for the short cleaning process is not required as illustrated in FIG. 10B. Therefore, in the reference example illustrated in FIG. 10A, the short cleaning process using TiBr₄ gas can be performed, with no waiting time for temperature control needed, which is required in the case where the cleaning process is performed after the film forming process and in the case where the film forming process is performed after the cleaning process. Accordingly, the deposits in the processing chamber 1, which may cause particles, can be removed by plasma etching using TiBr₄ gas without causing a decrease in throughput.

Referring back to FIG. 9, after the cleaning process using ClF₃ gas in step S70, the control device 7 performs a purging process in step S80 to exhaust ClF₃ gas. The purging process may be performed using N₂ gas or Ar gas.

After the purging process of step S80, the control device 7 forms a pre-coating film on each part in the processing chamber 1 in step S90. The gas supplied in the pre-coating step (Pre-Coating in FIGS. 10A and 10B) is preferably the same gas as the gas used for the film formation on the substrate W. Accordingly, the same film (for example, a TiN film or a Ti film) as the film formed by the film forming process of the substrate W is formed as a pre-coating film on each part in the processing chamber 1, and thus the film forming environment of the substrate W can be stabilized. After the coating with the pre-coating film, a next TiN film or Ti film is formed.

As described above, according to the film forming method of the present embodiment, it is possible to form a metal-containing film having good coverage. The metal-containing film can be formed from the bottom of the recess.

The film forming method according to the embodiment disclosed herein is merely an example in all respects and should not be construed as being limited thereto. The embodiments may be modified and improved in various forms without departing from the scope and spirit of the appended claims. The matters described in the plurality of embodiments can be combined with each other within a range not inconsistent with each other.

What is claimed is:

1. A film forming method, comprising:
(a) preparing a substrate in a processing chamber;
(b) forming a titanium nitride film in a recess formed on the substrate by supplying a film forming gas containing a metal-containing gas to the processing chamber;
(c) etching the titanium nitride film by supplying an etching gas containing a metal-containing gas to the processing chamber; and
(d) repeatedly performing (b) and (c) in this order, wherein
the metal-containing gas in (b) is TiBr₄ gas or TiCl₄ gas, and
the metal-containing gas in (c) is TiBr₄ gas.

2. A film forming method, comprising:
(a) preparing a substrate in a processing chamber;
(b) forming a titanium film in a recess formed on the substrate by supplying a gas containing a metal-containing gas to the processing chamber;
(c) etching the titanium film by supplying a gas containing a metal-containing gas to the processing chamber; and
(d) repeatedly performing (b) and (c) in this order, wherein
the metal-containing gas in (b) is TiCr₄ gas, and
the metal-containing gas in (c) is TiBr₄ gas.

3. The film forming method according to claim 1, wherein
in (c), the titanium nitride film is plasma-etched with plasma generated from TiBr₄ gas by supplying an RF power to the processing chamber.

4. The film forming method according to claim 2, wherein
in (c), the titanium film is plasma-etched with plasma generated from TiBr₄ gas by supplying an RF power to the processing chamber.

5. The film forming method according to claim 1, wherein
the metal-containing gas supplied in (b) and the metal-containing gas supplied in (c) are a same gas.

6. The film forming method according to claim 1, wherein
the metal-containing gas supplied in (b) and the metal-containing gas supplied in (c) are different gases.

7. The film forming method according to claim 1, wherein
in (b), the titanium nitride film is formed by an ALD method by alternately supplying the metal-containing gas and NH₃ gas.

8. The film forming method according to claim 2, wherein
in (b), the titanium film is formed by an ALD method by alternately supplying the metal-containing gas and H₂ gas.

9. The film forming method according to claim 1, wherein
a temperature of a stage on which the substrate is placed is a same in (b) and (c).

10. The film forming method according to claim 1, further comprising
(e) performing short cleaning of an inside of the processing chamber with TiBr₄ gas when the number of times of repeatedly performing (b) and (c) reaches a first set number of times in (d).

11. The film forming method according to claim 1, wherein
a temperature of the stage on which the substrate is placed is a same in (e), (b), and (c).

12. The film forming method according to claim 10, further comprising
(f) performing cleaning of an inside of the processing chamber with ClF₃ gas when the number of times of repeatedly performing (b) and (c) reaches a second set number of times in (d), the second set number of times being larger than the first set number of times.

13. The film forming method according to claim 1, wherein
(b) and (c) are continuously performed in the same processing chamber.

14. The film forming method according to claim 1, wherein
repeating performing of (c), after (b) is performed once or a plurality of times.

15. The film forming method according to claim 1, wherein
a temperature of a stage on which the substrate is placed is 350° C. to 530° C. in (c).

16. The film forming method according to claim 2, wherein
the metal-containing gas supplied in (b) and the metal-containing gas supplied in (c) are different gases.

17. The film forming method according to claim 2, wherein
a temperature of a stage on which the substrate is placed is a same in (b) and (c).

18. The film forming method according to claim 2, further comprising
(e) performing short cleaning of an inside of the processing chamber with TiBr₄ gas when the number of times of repeatedly performing (b) and (c) reaches a first set number of times in (d).

19. The film forming method according to claim 2, wherein
a temperature of the stage on which the substrate is placed is a same in (e), (b), and (c).

20. The film forming method according to claim 18, further comprising
(f) performing cleaning of an inside of the processing chamber with ClF₃ gas when the number of times of repeatedly performing (b) and (c) reaches a second set number of times in (d), the second set number of times being larger than the first set number of times.

21. The film forming method according to claim 2, wherein
(b) and (c) are continuously performed in the same processing chamber.

22. The film forming method according to claim 2, wherein
repeating performing of (c), after (b) is performed once or a plurality of times.

23. The film forming method according to claim 2, wherein
a temperature of a stage on which the substrate is placed is 350° C. to 530° C. in (c).
